(19) United States
(12) Patent Application Publication
(10) Pub. No.: US 2015/0138664 A1
(43) Pub. Date: May 21, 2015

(54) FPC ASSEMBLY AND DISK DRIVE

(71) Applicant: KABUSHIKI KAISHA TOSHIBA, Tokyo (JP)

(72) Inventors: Naoto AKATSUKA, Yokohama-shi (JP); Shinji FUJIMOTO, Yokohama-shi (JP); Yukihiro KOMURA, Yokohama-shi (JP); Akitoshi SUZUKI, Yokohama-shi (JP); Satoru SHIMIZU, Tokyo (JP)

(73) Assignee: KABUSHIKI KAISHA TOSHIBA, Tokyo (JP)

(21) Appl. No.: 14/193,238

(22) Filed: Feb. 28, 2014

Related U.S. Application Data
(60) Provisional application No. 61/906,001, filed on Nov. 19, 2013.

(51) Int. Cl. G11B 5/48; H05K 1/02

(52) U.S. Cl. CPC G11B 5/486; H05K 1/0281; H05K 1/0201; H05K 2201/062
USPC 360/46; 174/254

(57) ABSTRACT

According to one embodiment, there is provided an FPC (Flexible Printed Circuits) assembly including an FPC and a reinforcing plate The reinforcing plate reinforces a part of the FPC. The reinforcing plate has a first part and a second part. The first part is disposed in a part of the reinforcing plate and formed of a material whose main component is resin. The second part is disposed in a part other than the part of the reinforcing plate and formed of a material whose main component is metal.

### CROSS-REFERENCE TO RELATED APPLICATIONS

This application is based upon and claims the benefit of priority from Provisional Application No. 61/906001, filed on Nov. 19, 2013; the entire contents of which are incorporated herein by reference.

### FIELD

Embodiments described herein relate generally to an FPC assembly and a disk drive.

### BACKGROUND

The FPC (Flexible Printed Circuits) is a printed circuit board that is flexible and can be deformed significantly, and therefore is often attached to a movable member. For example, in the disk drive, a distal end side of the FPC is mounted to the side of the head stack assembly. Thus, in order to reinforce the strength of the distal end side of the FPC, a reinforcing plate (a reinforcing plate) is attached to the distal end side of the FPC. In this case, it is desirable to improve the performance such as thermal characteristics, mechanical characteristics, and the like of the FPC assembly including the FPC and the reinforcing plate.

### BRIEF DESCRIPTION OF THE DRAWINGS

FIG. 1 is a view illustrating a configuration of a disk drive to which an FPC assembly according to an embodiment is applied;

FIG. 2 is a perspective view illustrating a configuration of a part of an. actuator and the FPC assembly in the embodiment;

FIG. 3 is an exploded perspective view illustrating a configuration of a part of the actuator and the FPC assembly in the embodiment;

FIG. 4 is an enlarged perspective view illustrating a state where the FPC assembly is mounted to a head stack assembly according to the embodiment;

FIG. 5 is an enlarged perspective view illustrating a configuration viewed from the opposite side of a mounting surface of the FPC assembly according to the embodiment;

FIG. 6 is an enlarged perspective view illustrating a configuration viewed from the mounting surface side of the FPC assembly according to the embodiment;

FIG. 7 is an enlarged perspective view illustrating a mounted surface of the head stack assembly according to the embodiment;

FIG. 8 is an enlarged perspective view illustrating a configuration viewed from a mounting surface side of an FPC assembly according to a modification of the embodiment; and

FIG. 9 is an enlarged perspective view illustrating a configuration viewed from a mounting surface side of an FPC assembly according to another modification of the embodiment.

### DETAILED DESCRIPTION

In general, according to one embodiment, there is provided an FPC (Flexible Printed Circuits) assembly including an FPC and a reinforcing plate. The reinforcing plate reinforces a part of the ETC. The reinforcing plate has a first part and a second part. The first part is disposed in a part of the reinforcing plate and formed of a material whose main component is resin. The second part is disposed in a part other than the part of the reinforcing plate and formed of a material whose main component is metal.

Exemplary embodiments of an FPC assembly and a disk drive will be explained below in detail with reference to the accompanying drawings. The present invention is not limited to the following embodiments.

### Embodiment

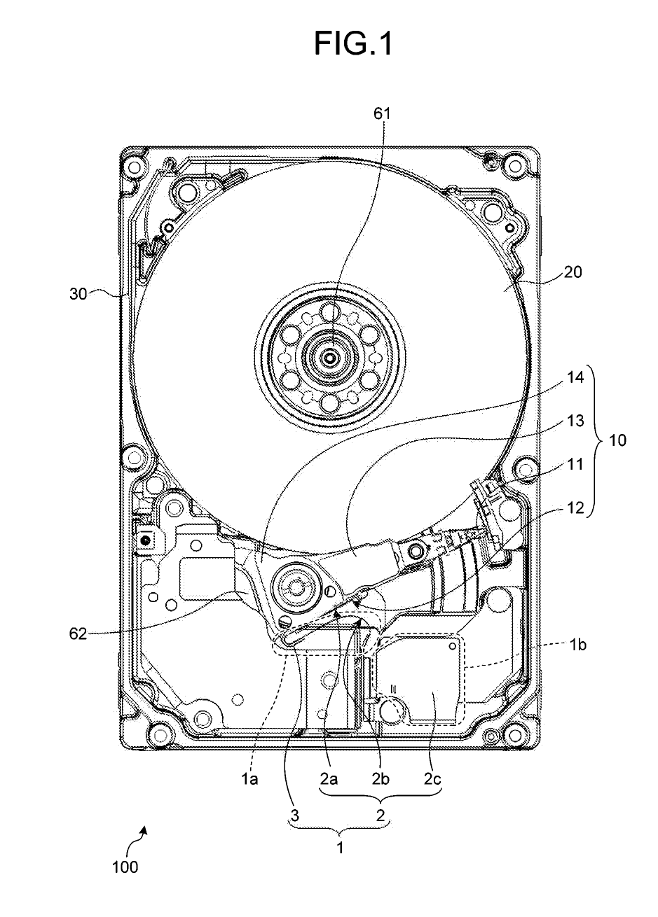

Firstly, by mainly referring to FIG. 1, the configuration of a disk drive 100 to which an FPC assembly 1 according to the embodiment is applied is described. FIG. 1 is a view illustrating the configuration. of the disk drive 100.

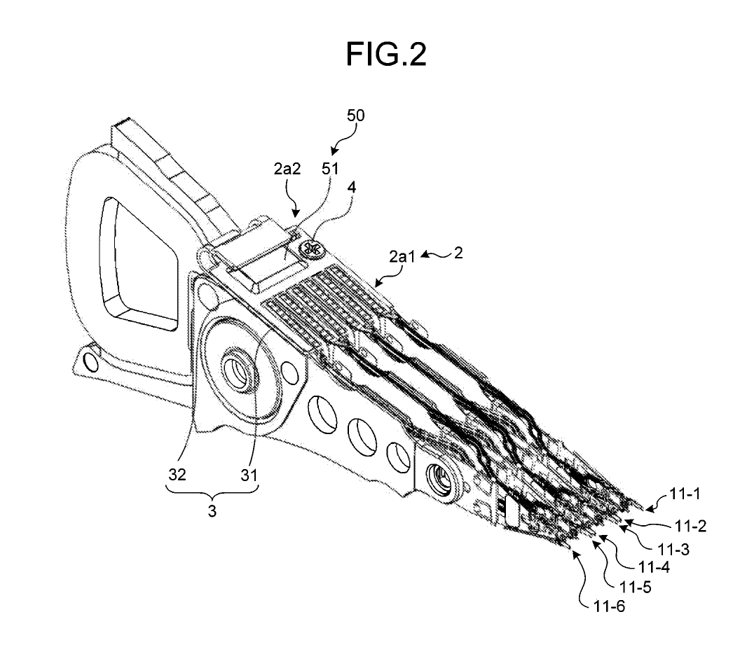

As illustrated in FIG. 1, the disk drive 100 includes a magnetic disk 20, a head stack assembly 10, the FPC assembly 1, and a control unit 50, The control unit 50 has a preamplifier 51 (see FIG. 2).

The magnetic disk 20, the head stack assembly 10, the FPC assembly 1, and the preamplifier 51 are accommodated in a case. The case has a top cover (not illustrated) and a base 30. The base 30 has an opened top and is formed in a rectangular box shape. The top cover is formed in a rectangular box shape corresponding to the base 30 the base 30. The top cover is screwed to the base 30 with a plurality of screws to cover the upper opening of the base 30.

The magnetic disk 20 is configured with a magnetic recording layer provided to a board (disk) The magnetic disk 20 has a size of 2.5 inches (6.35 cm), for example, and a plurality of (for example, three) magnetic disks are provided within the disk drive 100. A spindle motor 61 is fixed to the bottom wall of the base 30 to support the magnetic disk 20 and revolves the magnetic disk 20 according to the control by the control unit 50.

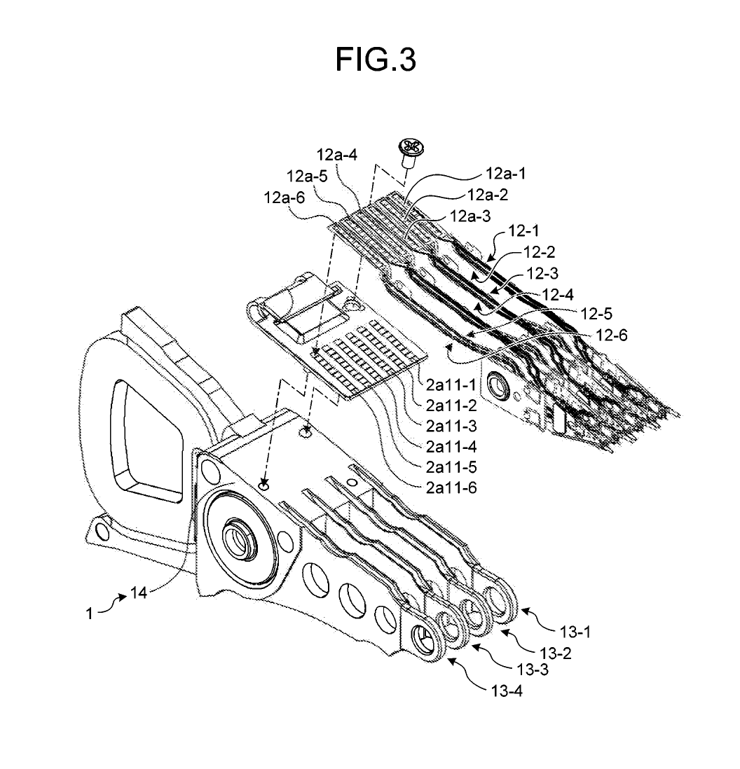

The head stack assembly (actuator) 10 has a magnetic head 11, an arm 13, a flexure 12, and a bearing part 14. A voice coil motor 62 is attached to the bottom wall of the base 30 and fixed to the bearing part 14 that supports the arm 13. The voice coil motor 62 causes the arm 13 to move toward the magnetic disk 20 side via the bearing part 14 according to the control by the control unit 50, and causes the magnetic head 11 to be positioned with respect to the magnetic disk 20. The flexure 12 is configured with a long, narrow flat spring that is able to be elastically deformed. The distal end of the flexure 12 is attached with the magnetic head 11 and is fixed to the distal end of the arm 13. A plurality of the magnetic heads 11, the arms 13, and the flexures 12 are provided so as to correspond to a plurality of (for example, three) magnetic disks 20 being provided, respectively (see FIG. 2, FIG. 3), It is noted that each flexure 12 may be formed with corresponding arm 13 in an integral manner. The magnetic head 11 writes information. to the magnetic disk 20 and reads out information from the magnetic disk 20 with the distal end of the arm 13 positioning above or below the magnetic disk 20.

The FPC assembly 1 has an FPC (Flexible Printed Circuits) 2 and a reinforcing plate 3. The FPC 2 is a printed board that is flexible and can be deformed significantly, and electrodes and wirings are patterned therein. The FPC assembly 1 is mounted to the side of the head stack assembly (actuator) 10. For example, in the FPC 2, its distal end side part 2a is mounted on the side of the head stack assembly 10, the other distal end side part 2c is fixed to the base 30 by a screw and the like, and a middle part 2b connects the distal end side part 2a to the other distal end side part 2c. That is, the FPC assembly 1 has a movable part la corresponding to the distal end side part. 2a and the middle part 2b of the FPC 2 and a fixed part lb corresponding to the other distal end side part 2c of the FPC 2. In the movable part 1a, the distal end side part 2a and the middle part 2b of the FPC 2 are movable in response that the head stack assembly 10 is moved by the voice coil motor 62. Then, in order to reinforce the strength of the distal end side part 2a of the FPC 2, a reinforcing plate (reinforcing plate) 3 is attached to the distal end side part 2a of the FPC 2. The details of the arrangement of the reinforcing plate 3 will be described later.

The electrode of the flexure 12 is electrically connected to the electrode near the distal end of the FPC 2. For example, the electrode of the flexure 12 is soldered to the electrode near the distal end of the FPC 2. The electrode of the flexure 12 is electrically connected to the magnetic head 11. In this case, the information to be written to the magnetic disk 20 is supplied to the magnetic head 11 from the control unit 50 via the FPC 2 and the flexure 12. Further, the information read out from the magnetic disk 20 by the magnetic head 11 is supplied to the control unit 50 via the flexure 12 and the FPC 2.

The control unit 50 has the preamplifier 51 and a controller (not illustrated). The preamplifier 51 is implemented to the FTC 2 (see FIG. 2). That is, the FPC 2 electrically connects the preamplifier 51 to the electrode of the flexure 12 via a first wiring and connects the preamplifier 51 to the controller via a second wiring.

The preamplifier 51 amplifies the signal corresponding to the information to be written to the magnetic disk 20 and amplifies the signal corresponding to the information read out from the magnetic disk 20. In this case, the preamplifier 51 generates heat in response to its operation.

The controller controls the magnetic head 11 via the preamplifier 51. For example, the controller generates the information. to be written to the magnetic disk 20 and supplies it to the preamplifier 51, and receives the information read out from the magnetic disk 20 and processes it.

Next, a part of the actuator 10 and the FPC assembly 1 will be described using FIG. 2 and FIG. 3. FIG. 2 is a perspective view illustrating the configuration of a part of the actuator 10 and the FPC assembly 1. FIG. 3 is an exploded perspective view illustrating the configuration of a part of the actuator 10 and the ETC assembly 1. In FIG. 2 and FIG. 3, for simplifying the depiction, the depiction of the middle part 2b and the other distal end side part 2c of the FPC 2 are omitted.

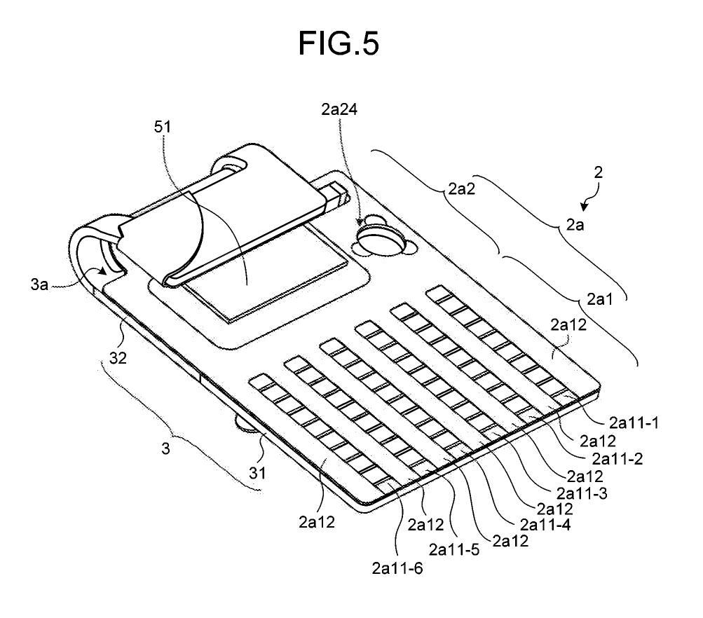

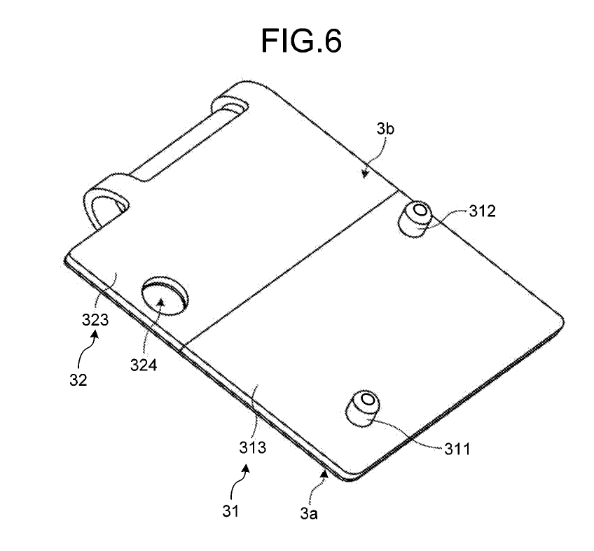

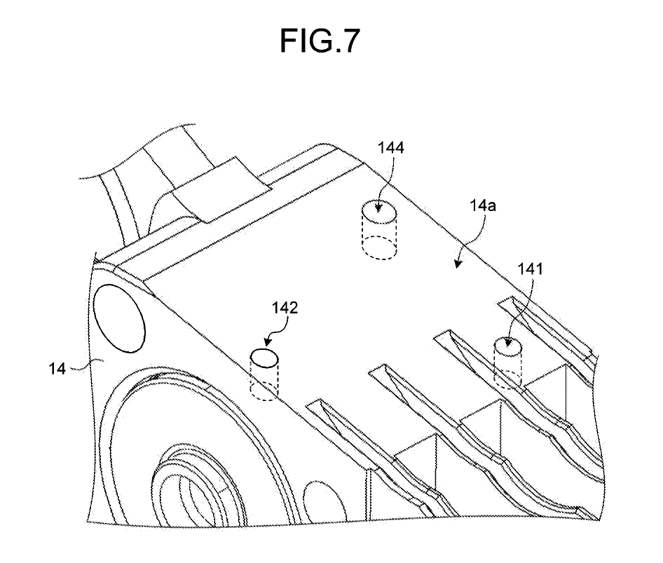

In the FPC assembly 1, the distal end side part 2a of the FPC 2 is attached to a non-mounting surface 3a (see FIG. 5) of the reinforcing plate (reinforcing plate) 3 by an adhesive. For the adhesive, employed may be an adhesive whose main component is the mixture of the epoxy resin and the acrylic resin, for example. The non-mounting surface 3a is the opposite surface of the mounting surface 3b (see FIG. 6) of the reinforcing plate 3. The mounting surface 3b is a surface on which the reinforcing plate 3 contacts to a mounted surface 14a (see FIG. 7) of the bearing part 14 when the FPC assembly 1 is mounted on the side part of the head stack assembly 10.

The distal end side part 2a of the FPC 2 has a first area 2a1 and a second area 2a2. The first area 2a1 is located in the magnetic head 11 side, that is, the distal end side in the distal end side part 2a. The second area 2a2 is located in the opposite side of the magnetic head 11, that is, the other distal end side in the distal end side part 2a.

The reinforcing plate 3 reinforces the distal end side part 2a of the FPC 2 and is mounted on the mounted surface 14a (see FIG. 7) of the bearing part 14. The reinforcing plate 3 has a first part 31 and a second part 32. The first part 31 is located. in the magnetic head 11 side, that is, the distal end side in the reinforcing plate 3. To the first part 31, the first area 2a1 is mainly attached by an adhesive. The second part 32 is located in the opposite side of the magnetic head 11, that is, the other distal end side in the reinforcing plate 3. To the second part 32, the second area 2a2 is mainly attached by an adhesive.

To the first area 2a1 of the FPC 2, electrodes of a plurality of flexures 12-1 to 12-6 are connected. Each of the flexures 12-1 to 12-6 is attached to the corresponding arm of a plurality of arms 13-1 to 13-4 and connected to the corresponding magnetic heads 11-1 to 11-6. For example, a plurality of electrode groups 12a-1 to 12a-6 electrically connected respectively to the corresponding magnetic heads 11-1 to 11-6 is provided to the plurality of flexures 12-1 to 12-6. Corresponding to the above, a plurality of electrode groups 2a11-1 to 2a11-6 is provided to the first area 2a1 of the FPC 2. Each of the electrode groups 2a11-1 to 2a11-6 is electrically connected with corresponding electrode groups 12a-1 to 12a-6 via the solder..

For example, in the process of a solder joint, it is necessary to dispose the soldering member between each of the electrode groups 2a11-1 to 2a11-6 of the first area 2a1 and the electrode groups 12a-1 to 12a-6 of the flexures 12-1 to 12-6 and heat them from the electrode groups 12a-1 to 12a-6 side by a soldering iron to melt the soldering member.

In this case, if a first part 31 of the reinforcing plate 3 attached to the first area 2a1 of the FPC 2 were formed of a material of high thermal conductivity such as metal, the heat of the soldering iron would be unlikely to remain in the vicinity of the soldering member and thus would be likely to be radiated via the first part 31. With the radiation of the heat from the soldering iron, the soldering members disposed between the electrode groups 2a11-1 to 2a11-6 and the electrode groups 12a-1 to 12a-6 would be unlikely to be melted, which would make it difficult to perform the solder joint of the electrode groups 2a11-1 to 2a11-6 and the electrode groups 12a-1 to 12a-6.

In contrast, in the present embodiment, the first part 31 is formed of a resin whose thermal conductivity is lower than the metal. The first part 31 may be formed of a thermal insulating resin (for example, epoxy resin, glass epoxy resin, polyimide resin, phenol resin, polystyrene resin, polyurethane resin, polyethylene resin, and the like). This allows the heat from the soldering Iron to remain in the vicinity of the soldering member when the soldering member is heated by the soldering iron from the electrode groups 12a-1 to 12a-6 in the process of the solder joint, so that the soldering member can be easily melted. This allows for easier solder Joint between the electrode groups 2a11-1 to 2a11-6 and the electrode groups 12a-1 to 12a-6.

In the second area 2a2 of the FPC 2, a package of the preamplifier 51 is implemented. The package of the preamplifier 51 has a plurality of terminals (not illustrated) in the lower side in FIG. 2 to FIG. 5. In the second area 2a2 is provided with a plurality of electrodes (not illustrated) electrically connected to the plurality of terminals of the preamplifier 51. Of the plurality of electrodes in the second area 2a2, a part of the electrodes is electrically connected to the electrode groups 2a11-1 to 2a11-6 of the first area 2a1 via the first wiring, and the other electrodes are electrically connected to the controller via the second wiring. The preamplifier 51 amplifies the signal to be supplied to the magnetic head 11 and amplifies the signal supplied from the magnetic head 11. The preamplifier 51 generates heat in response to such amplifying operation.

In this case, if a second part 32 of the reinforcing plate 3 attached to the second area 2a2 of the FPC 2 were formed of a material of low thermal conductivity such as resin, the heat generated from the preamplifier 51 would be likely to remain around the preamplifier 51. With the heat of the preamplifier 51 remaining around the preamplifier 51, the element (for example, transistor) in the preamplifier 51 would likely to be degraded by the heat. With the degradation of the element in the preamplifier 51 by the heat, the operation characteristics of the preamplifier 51 would be likely to be degraded.

In contrast, in the present embodiment, the second part 32 is formed of a metal whose thermal conductivity is higher than the resin. The second part 32 is formed of a material whose main component is aluminum. This allows the heat generated at the preamplifier 51 to be radiated to the bearing part 14 side via the second part 32 during the amplifying operation of the preamplifier 51. This allows for the suppression of the heat degradation of the element in the preamplifier 51 and thus allows for the suppression of the degradation of the operation characteristics of the preamplifier 51.

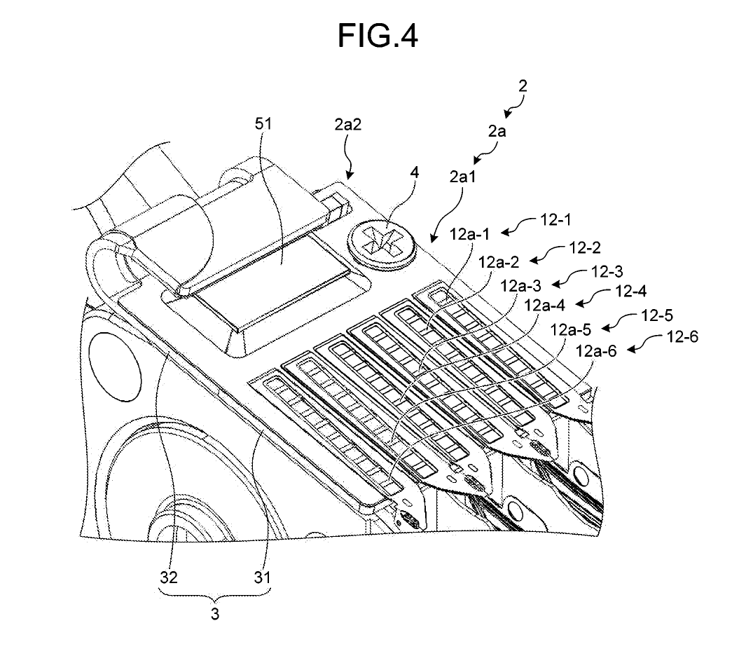

Next, the detailed configuration of the FPC assembly 1 will be described using FIG. 4 to FIG. 7. FIG. 4 is an enlarged perspective view illustrating a state where the FPC assembly 1 is mounted to the head stack assembly 10. FIG. 5 is an enlarged perspective view illustrating the configuration viewed from the opposite side of a mounting surface of the FPC assembly 1. FIG. 6 is an enlarged perspective view illustrating the configuration viewed from the mounting surface side of the FPC assembly 1. FIG. 7 is an enlarged perspective view illustrating the mounted surface of the head stack assembly 10. In FIG. 4 to FIG. 6, for simplifying the depiction, the depiction of the middle part 2b and the other part 2c of the FPC 2 are omitted.

In the distal end side part 2a of the FPC 2, a plurality of electrode groups 2a11-1 to 2a11-6 are provided to the first area 2a1, as illustrated in FIG. 5. Each of the electrode groups 2a11-1 to 2a11-6 is formed of a metal foil (for example, copper foil) on a substrate part 2a12. The substrate part 2a12 is formed of an insulating resin (for example, polyimide resin). Thereby, each of the electrode groups 2a11-1 to 2a11-6 is insulated to each other via the substrate part 2a12. Each of the electrode groups 2a11-1 to 2a11-6 has a shape corresponding to the electrode groups 12a-1 to 12a-6 of the flexures 12-1 to 12-6. For example, each of the electrode groups 2a11-1 to 2a11-6 is a strip shape arranged (in parallel) to each other in a plane view and extends from the distal end side to the other end side.

Further, the preamplifier 51 is implemented in the second area 2a2. In the second area 2a2, a hole 2a24 which a screw 4 illustrated in FIG. 4 is inserted is formed in the side of the area where the amplifier 51 is implemented as illustrated in FIG. 5. The diameter of the hole 2a24 is set larger than the diameter of the top of the screw 4 and smaller than the diameter of the head of the screw 4.

In the reinforcing plate 3, the first area 2a1 is mainly attached to the non-mounting surface 3a of the first part 31 as illustrated. in FIG. 5. The mounting surface 3b of the first part 31 is provided with pins 311 and 312 as illustrated in FIG. 6. That is, the first part 31 has a plate part 313 and a plurality of pins 311 and 312 Each of the pins 311 and 312 protrudes out of the mounting surface (main surface) 3b of the plate part 313. Each of the pins 311 and 312 protrudes to the bearing part 14 side, in the attitude when the reinforcing plate 3 is mounted to the bearing part 14. Correspondingly, the bearing part 14 is formed with holes 141 and 142 corresponding to the pins 311 and 312 in the mounted surface 14a. That is, the hole 141 is a hole into which the pin 311 is inserted and the hole 142 is a hole into which the pin 312 is inserted

The pins 311 and 312 are formed in substantially the column shape as illustrated in FIG. 6, for example. Correspondingly, the holes 141 and 142 of the bearing part 14 are formed in substantially the column shape as illustrated in FIG. 7. It is noted that the shape of the pins 311 and 312 may be other shape as long as it has the shape so as to protrude from the plate part 313 to the bearing part 14 side in the attitude when the reinforcing plate 3 is mounted to the bearing part 14. For example, the pins 311 and 312 may be a prism, or may be a corn or a pyramid that has the bottom in the plate part 313 side.

The second area 2a2 is mainly attached to the non-mounting surface 3a of the second part 32 as illustrated in FIG. 5. The mounting surface 3b of the second part 32 is provided with a hole 324 as illustrated in FIG. 6. The hole 324 is formed in a position corresponding to the hole 2a24 of the second area 2a2. That is, the second part 32 has the plate part 323 and the hole 324 The hole 324 is disposed at the position corresponding to the hole 2a24 of the second area 2a2 and passes through from the mounting surface 3b to the mounted surface 3a of the second part 32. Correspondingly, the bearing part 14 is provided with a threaded screw hole 144 in its mounted surface 14a. That is, the hole 324 is communicated to the hole 2a24, so that the screw 4 can be inserted into the hole 2a24 and the hole 324 and screwed with the threaded screw hole 144 of the bearing part 14.

In the reinforcing plate 3, since the first part 31 is formed of the material whose main component is resin and the second part 32 is formed of the material whose main component is metal as described above, the density of the first part 31 is lower than the density of the second part 32. The screwing of the reinforcing plate 3 to the bearing part 14 is done in the second part 32 side by the screw 4, Thereby, the center of gravity of the reinforcing plate 3 is located in the second part 32 side and the fixing point of the screwing is also located in the second part 32 side. With this structure only, however, the first part 31 is likely to vibrate upon the movement of the head. stack assembly In response to the vibration of the first part. 31, the magnetic heads 11-1 to 11-6 vibrate via the flexures 12-1 to 12-6, and therefore the magnetic heads 11-1 to 11-6 are unlikely to accurately read or write the information. It is thus required to provide a structure for suppressing the vibration of the first part 31.

Here, it is assumed that the first part 31 is also screwed in. order to suppress the vibration. of the first part 31. In this case, it would be difficult to fix the first part 31, and the first part 31 would be likely to be displaced because of the tolerance between the screw and the threaded screw hole. This would make it difficult to suppress the vibration of the first part 31 and make it difficult to accurately position the first part 31 with respect to the bearing part 14. Further, it would be necessary to enlarge the first part 31 in the lateral direction in FIG. 5 and form a hole used for inserting the screw and, accordingly, a higher top cover of the case would be necessary. Thereby, the disk drive 100 would be larger and the manufacturing cost of the disk drive 100 would be increased.

In contrast, in the present embodiment, the pins 311 and 312 of the first part 31 are inserted into the holes 141 and 142 of the bearing part 14 and thus the first part 31 can be easily fixed, which can facilitate the suppression of the vibration of the first part 31 and the positioning of the first part 31 with respect to the bearing part 14. Further, this can suppress the disk drive 100 to be increased in size, allowing for the reduction of the manufacturing cost of the disk drive 100.

Further, it is assumed that, in order to suppress the vibration of the first part 31, the adhesive are injected to the gap between the first part 31 and the bearing part 14 with the reinforcing plate 3 screwed to the bearing part 144 In this case, the adhesive is unlikely to be infused into the gap between the first part 31 and the bearing part 14 and therefore the adhesive strength between the first part 31 and the bearing part 14 is likely to be insufficient for the required strength, which makes it difficult to suppress the vibration of the first part 31,

In contrast, in the present embodiment, the pins 311 and 312 of the first part 31 are inserted to the holes 141 and 142 of the bearing part 14, so that the first part 31 can be easily fixed without using the adhesive, which can facilitate the suppression of the vibration of the first part 31. Further, the pins 311 and 312 of the first part 31 allow the first part 31 to be easily positioned with respect to the bearing part 14.

In the reinforcing plate 3, the density of the first part 31 is lower than the density of the second part 32 as described above, resulting in the structure whose center of gravity is located in the second part 32 side. That is, the proper selection of the material of the first part 31 (the material whose main component is resin) and the material of the second part 32 (the material whose main component is metal) allows the center of gravity of the reinforcing plate 3 to be adjusted to the proper position in the second part 32 side according to the ratio of the density of the first part 31 and the density of the second part 32.

Further, in the reinforcing plate 3, as illustrated in FIG. 4 to FIG. 6, the first part 31 and the second part 32 are integrally molded. Further, in the first part 31, the plate part 313 and the pins 311 and 312 are integrally molded.

For example, the second part 32 can be formed by a sheet metal working of the metal plate. After the second part 32 is set to the mold for the resin molding, the resin that is to be the first part 31 is poured in the mold. Thereby, the first part 31 and the second part 32 can be integrally molded and the plate part 313 and the pins 311 and 312 can be integrally molded.

As set forth, in the embodiment, the first part 31 to which the flexures 12-1 to 12-6 are connected is disposed in the distal end side in the reinforcing plate 3 and formed of the material whose main component is resin in the FPC assembly 1. The second part 32 where the preamplifier 51 is mounted is disposed in the other end side in the reinforcing plate 3 and formed of the material whose main component is metal. For example, the thermal conductivity of the first part 31 is lower than the thermal conductivity of the second part 32 in the reinforcing plate 3. The first part 31 is formed of a heat insulation resin, for example This allows the heat of the soldering iron to remain around the soldering member in the solder joint process and allows the heat generated from the preamplifier 51 to be dispersed to the bearing part 14 side via the second part 32 with the FPC assembly 1 mounted on the head stack assembly 10. As a result, both easier solder joint in the solder joint process and suppression. of the heat degradation of the element in the preamplifier 51 can be easily achieved at the same time.

Further, in the embodiment, the density of the first part 31 is lower than the density of the second part 32 in the reinforcing plate 3 of the FPC assembly 1. Thereby, the weight of the reinforcing plate 3 can be reduced compared to the case where the entire reinforcing plate 3 is formed of the same material as the second part 32, which allows for a faster operation of the head stack assembly 10 on which the FPC assembly 1 is mounted.

Further, in the embodiment, the density of the first part 31 is lower than the density of the second part 32 in the reinforcing plate 3 of the FPC assembly 1, resulting in the structure whose center of gravity is located in the second part 32 side That is, the proper selection of the material of the first part 31 and the material of the second part 32 allows the center of gravity of the reinforcing plate 3 to be adjusted to the proper position in the second part 32 side according to the ratio of the density of the first part 31 and the density of the second part 312 Further, the first part 31 and the second part 32 are formed of the different materials, so that the shape and/or the thickness of the both can be independently determined. This can facilitate the improvement of the flexibility in the adjustment of the center of gravity balance of the head stack assembly 10 on which the FPC assembly 1 is mounted.

Further, in the embodiment, the first part 31 has the pins 311 and 312 protruding out of the mounting surface 3b of the plate part 313 to the head stack assembly 10 side in the reinforcing plate 3 of the FPC assembly 1. The head stack assembly 10 has the holes 141 and 142 corresponding to the pins 311 and 312 in the mounted surface 14a of the bearing part 14. This allows the reinforcing plate 3 to be easily positioned with respect to the bearing part 14 and easily fixed to the bearing part 14 when the FPC assembly 1 is mounted to the side of the head stack assembly 10. As a result, the positioning accuracy of the reinforcing plate 3 with respect to the bearing part 14 can be improved and the vibration of the first part 31 can be suppressed.

Further, in the embodiment, the first part 31 and the second part 32 are integrally molded and the plate part 313 and the pins 311 and 312 of the first part 31 are integrally molded in the reinforcing plate 3 of the FPC assembly 1. Thereby, the integral molding of the first part 31 and the second part 32 can be made at the same time as the integral molding of the plate part 313 and the pins 311 and 312 of the first part 31. As a result, the number of process for manufacturing the reinforcing plate 3 can he reduced allowing for the reduced manufacturing cost of the FPC assembly 1.

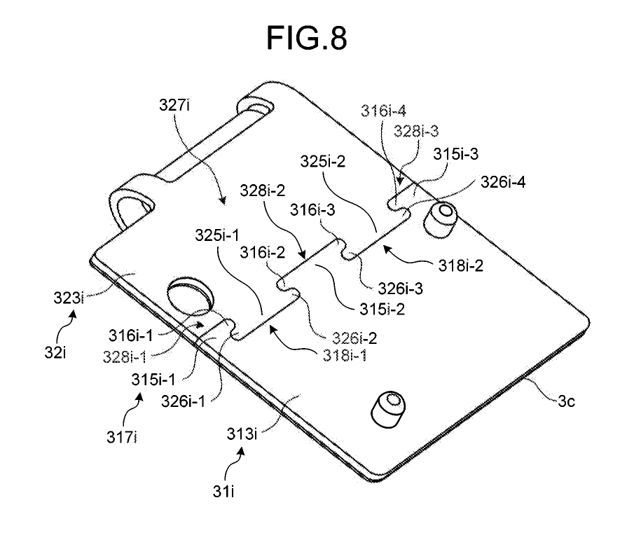

It is noted that, although FIG. 6 exemplifies the case where the boundary of the first part 31 and the second part 32 is liner, it may be structured such that a first part 31i and a second part 32i are engaged to each other as illustrated in FIG. 8. This can facilitate the improvement of the joint strength at the boundary of the first part 31i and the second part 32i.

For example, as illustrated in FIG. 8, the first part 31i has an engagement structure 317i and the second part 321 has an engagement structure 327i. The engagement structure 317i and the engagement structure 327i are configured to engage to each other.

Specifically, the engagement structure 317i has a plurality of convex portions 315i-1 to 315i-3 and a plurality of concave portions 318i-1 to 318i-2. Each of the convex portions 315i-1 to 315i-3 protrudes from the first part 31i to the second part 32i side. The plurality of concave portions 318i-1 to 318i-2 is formed between the plurality of convex portions 315i-1 to 315i-3.

The engagement structure 327i has a plurality of convex portions 325i-1 to 325i-2 and a plurality of concave portions 328i-I to 328i-3. Each of the convex portions 3251-1 to 3251-2 protrudes from the second part 32i to the first part 31i side The plurality of concave portions 328i-1 to 328i-3 is formed between the plurality of convex portions 315i-1 to 315i-2 and in both of the first part 31i and the second part 32i.

In the engagement structure 317i and the engagement structure 327i, the plurality of convex portions 315i-1 to 315i-3 are configured to engage with the plurality of concave portions 328i-1 to 328i-3. The plurality of convex portions 325i-1 to 325i-2 is configured to engage with the plurality of concave portions 318i-1 to 318i-2

Furthermore, the engagement structure 317i may have a plurality of sub-convex portions 316i-1 to 316i-4 as illustrated in FIG. 8, for example. Each of the sub-convex portions 316i-1 to 316i-4 extends along the end surface 3c in the distal end side of the reinforcing plate 3 from the tip of corresponding convex portions 315i-1 to 315i-3.

Sub-concave portions are formed between respective sub-convex portions 316i-1 to 316i-4 and the plate part 313i.

The engagement structure 327i may have a plurality of sub-convex portions 326i-1 to 326i-4. Each of the sub-convex portions 326i-1 to 326i-4 extends along the end surface 3c in the distal end side of the reinforcing plate 3 from the tip of corresponding convex portions 325i-1 to 325i-2. Sub-concave portions are formed. between respective sub-convex portions 326i-1 to 326i-4 and the plate part 323i.

In the engagement structure 317i and the engagement structure 327i, the plurality of sub-convex portions 316i-1 to 316i-4 are configured to engage with the plurality of sub-concave portions between the sub-convex portion 316i-1 to 316i-4 and the plate part 313i. The plurality of sub-convex portions 326i-1 to 326i-4 is configured to engage with the plurality of sub-concave portions between the sub-convex portion 326i-1 to 326i-4 and the plate part 323i.

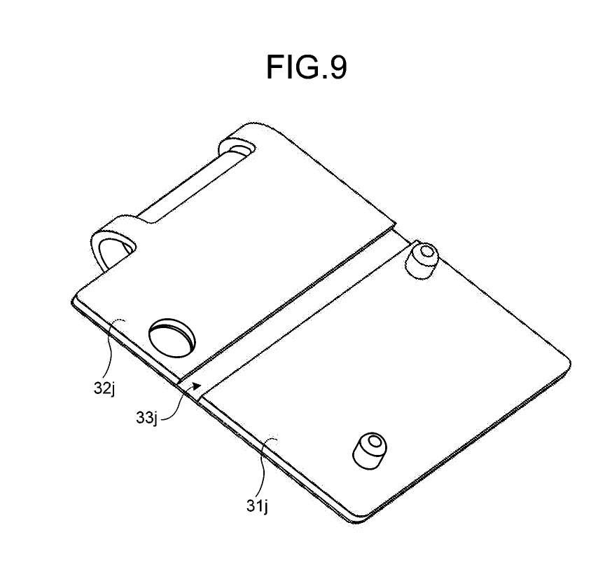

Alternatively, as illustrated in FIG. 9, a first part 31j and a second part 32j may reinforce the FPC 2, respectively, with being distant to each other in the reinforcing plate 3. For example, in the reinforcing plate 3, a gap 33j is formed between the first part 311 and the second part 32j when the first area 2a1 (see FIG. 5) of the FPC 2 is attached to the first part 31j and the second area 2a2 (see FIG. 5) of the FPC 2 is attached to the second part 32j. This allows for the thermal insulation between the first part 31j and the second part 32j, so that both easier solder joint in the solder joint process and suppression of the thermal degradation of the element in the preamplifier 51 can be more easily achieved at the same time.

While certain embodiments have been described, these embodiments have been presented by way of example only, and are not intended to limit the scope of the inventions Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. An FPC (Flexible Printed Circuits) assembly comprising:
an FPC; and
a reinforcing plate reinforcing a part of the FPC, wherein the reinforcing plate has:
a first part disposed in a part of the reinforcing plate and formed of a material whose main component is resin, and
a second part disposed in a part other than the part of the reinforcing plate and formed of a material whose main component is metal, the second part being not overlapped with the first part.

2. The FPC assembly according to claim 1, wherein a thermal conductivity of the first part is lower than a thermal conductivity of the second part.

3. The FPC assembly according to claim 2, wherein the first part is formed of a heat insulating resin.

4. The FPC assembly according to claim 1, wherein a density of the first part is lower than a density of the second part.

5. The FPC assembly according to claim 1, wherein the first part has:
a plate part, and
a pin protruding from a main surface of the plate part.

6. The FPC assembly according to claim 5, wherein the first part has a plurality of pins.

7. The FPC assembly according to claim 5, wherein, in the first part, the plate part and the pin are integrally molded.

8. The FPC assembly according to claim 1, wherein, in the reinforcing plate, the first part and the second part are integrally molded.

9. The FPC assembly according to claim 8, wherein the first part and the second part are engaged with each other, respectively.

10. The FPC assembly according to claim 1, wherein, in the reinforcing plate, the first part and the second part reinforce the FPC, respectively, with being distant to each other.

11. A disk drive comprising:
a head stack assembly;
an FPC (Flexible Printed Circuits) assembly mounted on a side of the head stack assembly; and
a control unit,
wherein the head stack assembly has:
a magnetic head configured to read and write information to a magnetic disk, and
a flexure connected to the magnetic head, wherein the control unit has:
a preamplifier, and
a controller configured to control the magnetic head via the preamplifier,
wherein the FPC assembly includes:
an FPC, and
a reinforcing plate reinforcing a part of the FPC, and
wherein the reinforcing plate has:
a first part to which the flexure is connected and formed of a material whose main component is resin, and
a second part on which the preamplifier is mounted and formed of a material whose main component is metal, the second part being overlapped with the first part.

12. The disk drive according to claim 11, wherein a thermal conductivity of the first part is lower than a thermal conductivity of the second part.

13. The disk drive according to claim 12, wherein the first part is formed of a heat insulating resin.

14. The disk drive according to claim 11, wherein a density of the first part is lower than a density of the second part.

15. The disk drive according to claim 11, wherein the first part has:
a plate part, and
a pin protruding from a mounting surface of the plate part to the head stack assembly side, and
the head stack assembly has a hole corresponding to the pin in a mounted surface.

16. The disk drive according to claim 15, wherein
the first part has a plurality of pins, and
the head stack assembly has a plurality of holes corresponding to the plurality of pins.

17. The disk drive according to claim 15, wherein, in the first part, the plate part and the pin are integrally molded.

18. The disk drive according to claim 11, wherein, in the reinforcing plate, the first part and the second part are integrally molded.

19. The disk drive according to claim 18, wherein the first part and the second part are engaged with each other, respectively.

20. The disk drive according to claim 11, wherein, in the reinforcing plate, the first part and the second part reinforce the FPC, respectively, with being distant to each other.
